(19) United States
(12) Patent Application Publication
(10) Pub. No.: US 2021/0175108 A1
(43) Pub. Date: Jun. 10, 2021

(54) MULTI-POLAR CHUCK FOR PROCESSING OF MICROELECTRONIC WORKPIECES

(71) Applicant: Tokyo Electron Limited, Tokyo (JP)

(72) Inventor: Melvin Verbaas, Yamanashi (JP)

(21) Appl. No.: 17/097,953

(22) Filed: Nov. 13, 2020

Related U.S. Application Data
(60) Provisional application No. 62/944,078, filed on Dec. 5, 2019.

(51) Int. Cl. H01L 21/683; G03F 7/20

(52) U.S. Cl. CPC H01L 21/6833; H01L 21/6875; G03F 7/70708

(57) ABSTRACT

Methods and system are disclosed for multipolar electrostatic chucks (ESCs) that provide improved clamping of microelectronic workpieces within processing equipment. The disclosed multipolar ESCs effectively clamp microelectronic workpieces including those with significant bows. Multipolar ESC embodiments include a dielectric body and multiple sets of electrodes formed within the dielectric body. Further, multiple electric fields are generated between the multiple sets of electrodes to facilitate the processing of the microelectronic workpiece. For example, a voltage generator can be used to apply voltages to the multiple sets of electrodes to generate the multiple electric fields. These electric fields can migrate charge to edges of a microelectronic workpiece and can be used to facilitate clamping of the microelectronic workpiece and/or to reduce bow in a microelectronic workpiece. Sensors can also be used to help control and improve the operation of the multipolar ESCs.

### CROSS REFERENCE TO RELATED PATENTS AND APPLICATIONS

This application claims priority to and the benefit of the filing date of U.S. Provisional Patent Application No. 62/944,078, filed Dec. 5, 2019, which application is incorporated herein by reference in its entirety.

### BACKGROUND

The present disclosure relates to systems and methods for the manufacture of microelectronic workpieces.

Device formation within microelectronic workpieces typically involves a series of manufacturing techniques related to the formation, patterning, and removal of a number of layers of material on a substrate. To meet the physical and electrical specifications of current and next generation semiconductor devices, process flows are being requested to reduce feature size while maintaining structure integrity for various patterning processes.

For many processes, it is important for a microelectronic workpiece, such as a semiconductor wafer, to remain clamped in place within processing equipment. Bowing of the wafer, however, can cause significant problems in maintaining this clamped state. For example, a large amount of bow (e.g., greater than 0.5 millimeter) can occur in wafers during processes to form vertical NAND (V-NAND) devices for FLASH memories. This bowing can cause conventional monopolar electrostatic chucks and bipolar electrostatic chucks to be unable to adequately clamp the wafer. In particular, large bows can create sufficient distance between the wafer surface and the chuck surface such that electrostatic forces generated by these conventional techniques are not sufficient to overcome the distance caused by the bowing. This failure in the clamping provided by the monopolar or bipolar electrostatic chuck leads to device failures in the resulting microelectronic workpieces after manufacture.

FIG. 1A (Prior Art) is a cross-section diagram of an example embodiment 100 where a bipolar electrostatic chuck (ESC) 110 operates to clamp a microelectronic workpiece 112, such as a semiconductor wafer. The bipolar ESC 110 includes a dielectric body 102 within which is embedded two concentric electrodes 104 and 106. For the example embodiment shown, it is assumed that the microelectronic workpiece 112 is a disc. The first electrode 104 is circular and is positioned within the middle of bipolar ESC 110. The second electrode 106 is a ring positioned concentrically around the first electrode 104. To generate an electric field 115 between the electrodes 104/106, a positive voltage (V+) 105 is applied to the first electrode 104, and a negative voltage (V−) 107 is applied to the second electrode 106. These polarities can be reversed and alternating current (AC) signals can also be applied to form an electric field. The electric field 115 causes charge to build up on the bottom surface of the microelectronic workpiece 112. This charge combined with the electric field 115 causes an electrostatic force 108 to be asserted on the microelectronic workpiece 112. This electrostatic force 108 is dependent in part on the distance between the bipolar ESC 110 and the microelectronic workpiece 112. Where the microelectronic workpiece 112 is significantly bowed, the distance 114 between the bottom surface of the microelectronic workpiece 112 and the top surface of the bipolar ESC 110 can become large enough to reduce the electrostatic force 108 such that the bipolar ESC 110 is not able to clamp the microelectronic workpiece 112.

FIG. 1B (Prior Art) is a cross-section diagram of an example embodiment 150 where a monopolar electrostatic chuck (ESC) 160 operates to clamp a microelectronic workpiece 112, such as a semiconductor wafer. The monopolar ESC 160 includes a dielectric body 152 within which is embedded an electrode 154. For the example embodiment shown, it is assumed that the microelectronic workpiece 112 is a disc. The electrode 154 is circular and is positioned within the middle of monopolar ESC 160. To generate an electric field 165 between the electrode 154 and the microelectronic workpiece 112, a positive voltage (V+) 105 is applied to the electrode 154. This polarity can be reversed. The applied voltage causes an opposite charge to build up on the bottom surface of the microelectronic workpiece 112. This opposite charge forms the electric field 165 and causes an electrostatic force 158 to be asserted on the microelectronic workpiece 112. This electrostatic force 158 is dependent in part on the distance between the monopolar ESC 160 and the microelectronic workpiece 112. Where the microelectronic workpiece 112 is significantly bowed, the distance 114 between the bottom surface of the microelectronic workpiece 112 and the top surface of the monopolar ESC 160 can become large enough to reduce the force 158 such that the monopolar ESC 160 is not able to clamp the microelectronic workpiece 112.

### SUMMARY

Embodiments are described herein for multipolar electrostatic chucks (ESCs) that facilitate the manufacture of microelectronic workpieces within processing equipment. Different or additional features, variations, and embodiments can also be implemented, and related systems and methods can be utilized as well.

For one embodiment, a system is disclosed including a multipolar ESC and a voltage generator. The multipolar ESC includes a dielectric body and multiple sets of electrodes formed within the dielectric body. The voltage generator is coupled to the multiple sets of electrodes for the multipolar ESC, and the voltage generator is configured to apply voltages to the multiple sets of electrodes to generate multiple electric fields between the multiple sets of electrodes.

In additional embodiments, the multiple electric fields are configured to migrate charge to edges of a microelectronic workpiece. In further embodiments, the multiple electric fields are configured to facilitate clamping of a microelectronic workpiece. In further embodiments, the multiple electric fields are configured to reduce bow in a microelectronic workpiece. In still further embodiments, the multiple sets of electrodes include at least three sets of electrodes.

In additional embodiments, the multiple electric fields are sequentially pulsed from a center of the dielectric body to outer edges of the dielectric body. In further embodiments, pulsing for the multiple electric fields overlap with each other. In further additional embodiments, one or more varying voltages are applied to the multiple sets of electrodes.

In additional embodiments, the system also includes one or more sensors associated with a microelectronic workpiece. In further embodiments, the voltage generator is further configured to adjust voltages applied to the multiple sets of electrodes based upon one or more parameters detected by the one or more sensors. In still further embodiments, the one or more parameters includes a bow in the microelectronic workpiece.

For one embodiment, a method is disclosed including positioning a microelectronic workpiece on a multipolar ESC, where the multipolar ESC includes a dielectric body and multiple sets of electrodes formed within the dielectric body, and generating multiple electric fields between the multiple sets of electrodes by applying voltages to the multiple sets of electrodes.

In additional embodiments, the method includes using the multiple electric fields to migrate charge to edges of the microelectronic workpiece. In further embodiments, the method includes using the multiple electric fields to facilitate clamping of the microelectronic workpiece. In still further embodiments, the method includes using the multiple electric fields to reduce bow in the microelectronic workpiece.

In additional embodiments, the generating includes sequentially pulsing the multiple electric fields from a center of the dielectric body to outer edges of the dielectric body. In further embodiments, the generating also includes overlapping the pulsing for the multiple electric fields.

In additional embodiments, the generating includes applying one or more varying voltages to the multiple sets of electrodes. In further embodiments, the method also includes adjusting voltages applied to the multiple sets of electrodes based upon one or more parameters detected by the one or more sensors associated with the microelectronic workpiece. In still further embodiments, the one or more parameters includes a bow in the microelectronic workpiece.

Different or additional features, variations, and embodiments can also be implemented, and related systems and methods can be utilized as well.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1A (Prior Art) is a cross-section diagram of an example embodiment where a bipolar electrostatic chuck (ESC) operates to clamp a microelectronic workpiece, such as a semiconductor wafer.

FIG. 1B (Prior Art) is a cross-section diagram of an example embodiment where a monopolar electrostatic chuck (ESC) operates to clamp a microelectronic workpiece, such as a semiconductor wafer.

FIG. 2A is a cross-section view of an example embodiment where a multipolar electrostatic chuck (ESC) according to the disclosed embodiments includes multiple sets of electrodes and where multiple electric fields generated between these electrodes facilitate the processing of a microelectronic workpiece 112, such as a semiconductor wafer.

FIG. 2B is a top view for the electrodes formed in the multipolar ESC of FIG. 2A.

FIG. 2C is a process flow diagram of an example embodiment where multiple electric fields generated between electrodes in a multipolar ESC are used to facilitate processing of a microelectronic workpiece.

FIG. 3A is a timing diagram of an example embodiment where one or more algorithms are applied to generate electric fields sequentially with respect to the electrodes formed in the multipolar ESC of FIGS. 2A-2B.

FIG. 3B is a diagram of an embodiment where charge accumulated on a microelectronic workpiece has migrated to the edge of the microelectronic workpiece based upon the sequential pulsing of the electric fields in FIG. 3A.

FIG. 4 provides one example embodiment for a plasma processing system that can use the disclosed multipolar ESC embodiments and is provided only for illustrative purposes.

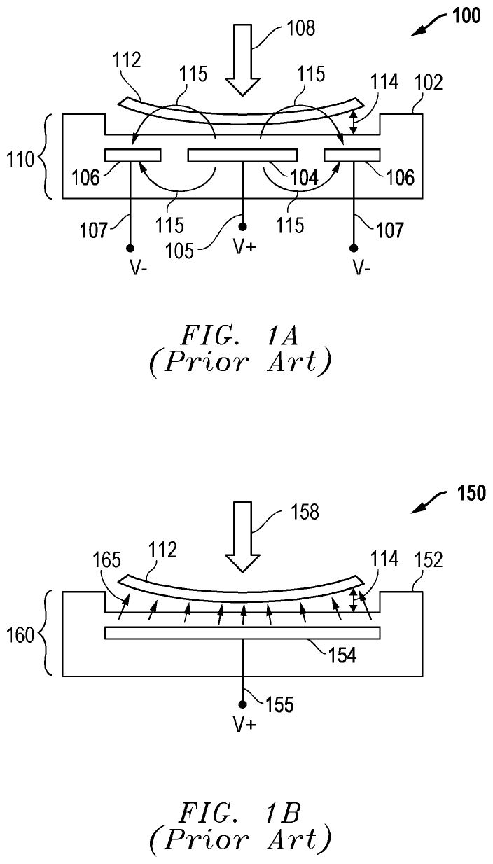

### DETAILED DESCRIPTION

Methods and system are disclosed for multipolar ESCs that facilitate processing of microelectronic workpieces and provide improved clamping for microelectronic workpieces within processing equipment. The disclosed multipolar ESCs effectively clamp microelectronic workpieces, such as semiconductor wafers, including those with significant bows, such as bows greater than 0.5 millimeters. A variety of advantages and implementations can be achieved while taking advantage of the process techniques described herein.

For one embodiment, multiple different sets of electrodes are included within a dielectric body for a multipolar ESC. Voltages applied to these sets of electrodes are controlled to form multiple different electric fields. For one embodiment, the different electric fields are generated to migrate charge within the multipolar ESC thereby improving the clamp of microelectronic workpiece. Further, sensors can be used to detect bow conditions and/or other conditions, and one or more voltage control algorithms can be applied to facilitate the clamping of the microelectronic workpiece. Although concentric ring embodiments are shown and described below for the different sets of electrodes, the disclosed techniques can also be applied to other electrode configurations. Further, the disclosed multipolar ESCs can be used in a variety of different processes for the manufacture of microelectronic workpieces including etch processes, lithography processes, deposition processes, high-temperature deposition processes (e.g., aluminum nitride deposition), and/or other processes. Further, the multipolar ESCs can be used in a variety of different processing equipment for the manufacture of microelectronic workpieces. For example, the multipolar ESCs can be used in multi-stage heaters, front-end wafer processing equipment, processing equipment used to manufacture V-NAND memories, and/or other processing equipment used in the manufacture of microelectronic workpieces. Other applications can also be implemented while still taking advantage of the techniques described herein.

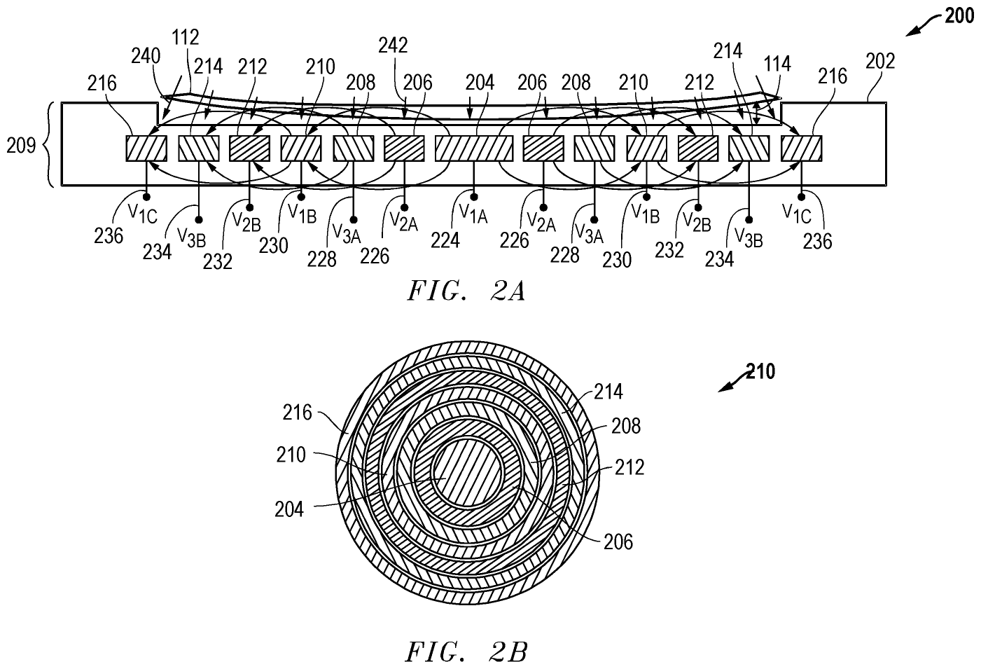

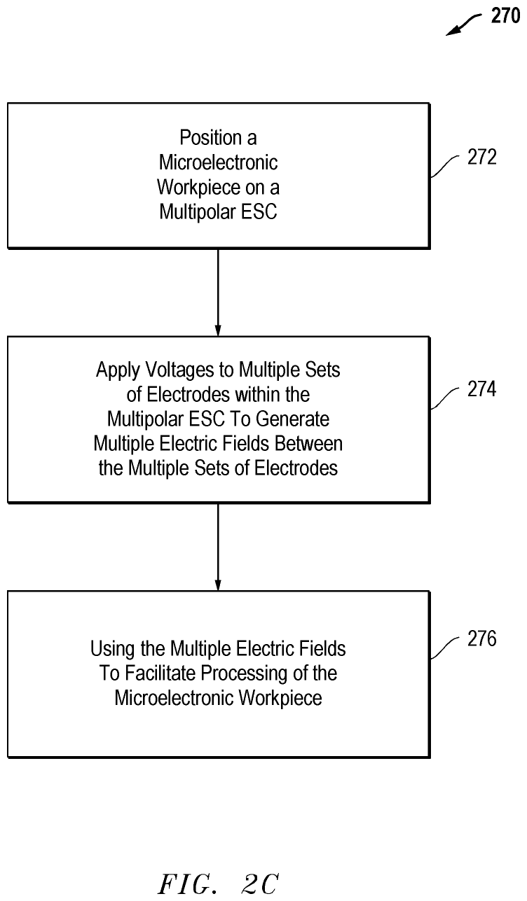

FIG. 2A is a cross-section view of an example embodiment 200 for a multipolar electrostatic chuck (ESC) 209 according to the disclosed embodiments that includes multiple sets of electrodes where multiple electric fields generated between these electrodes facilitate processing of a microelectronic workpiece 112, such as a semiconductor wafer. The multipolar ESC 210 includes a dielectric body 202, and multiple sets of electrodes are formed or embedded within the dielectric body 202. For the example embodiment shown, a first set of electrodes includes electrodes 204 and 210; a second set of electrodes includes electrodes 206 and 212; a third set of electrodes includes electrodes 208 and 214; and a fourth set of electrodes includes electrodes 210 and 216. For this example embodiment, it is assumed that the microelectronic workpiece 112 is a disc. The electrode 204 is circular and is positioned within the middle of multipolar ESC 209. The other electrodes 206, 208, 210, 212, 214, and 216 are rings positioned concentrically around the electrode 204. Although concentric rings are used for this embodiment, it is again noted that additional and/or different configurations could also be used.

To generate an electric field between the different sets of electrodes, differential voltages are applied between the electrodes. For example, a positive voltage (V+) can be applied to one electrode with the set of electrodes, and a negative voltage (V−) can be applied to a second electrode within the set of electrodes. These polarities can also be reversed, and alternating current (AC) signals and/or other varying voltage signals can also be applied to the electrodes to generate the electric field. For one example embodiment, an electric field is generated between electrodes 204 and 210 by applying a voltage (V_{1A}) 224 with a first polarity to electrode 204 and a voltage (V_{1B}) 230 with an opposite polarity to electrode 210. An electric field is generated between electrodes 210 and 216 by applying a voltage (V_{1B}) 220 with a first polarity to electrode 210 and a voltage (V_{1C}) 236 with an opposite polarity to electrode 216. An electric field is generated between electrodes 206 and 212 by applying a voltage (V_{2A}) 226 with a first polarity to electrode 206 and a voltage (V_{2B}) 232 with an opposite polarity to electrode 212. An electric field is generated between electrodes 208 and 214 by applying a voltage (V_{3A}) 228 with a first polarity to electrode 208 and a voltage (V_{3B}) 234 with an opposite polarity to electrode 214.

Once generated, the electric fields cause charge to build up on the bottom surface of the microelectronic workpiece 112. This charge combined with the electric field causes forces to be asserted on the microelectronic workpiece 112. These forces are dependent in part on the distance between the multipolar ESC 209 and the microelectronic workpiece 112. Where the microelectronic workpiece 112 is significantly bowed, the distance 114 between the bottom surface of the microelectronic workpiece 112 and the top surface of the multipolar ESC 209 can become large. In contrast with prior monopolar ESC and bipolar ESC solutions, however, the multipolar ESC embodiments described herein can still effectively clamp a microelectronic workpiece that has a large amount of bow (e.g., greater than 0.5 millimeter). This result is achieved in part by controlling the timing and size of the multiple different electric fields for the multipolar ESC 209. As such, the electrostatic force 240 formed at the edge of the microelectronic workpiece 112 can be made stronger as compared, for example, to the electrostatic force 242 formed closer to the center of the microelectronic workpiece 112. This increased force at the edges of the microelectronic workpiece 112 facilitates the clamping of the microelectronic workpiece 112 to the multipolar ESC 209. Further, this increased force can help to reduce the bow in the microelectronic workpiece 112. Other advantages can also be achieved.

FIG. 2B is a top view of the electrodes 204, 206, 208, 210, 212, 214, and 216 formed within the multipolar ESC 209 of FIG. 2A. It is noted that a portion of the dielectric body is positioned between each of the electrodes 204, 206, 208, 210, 212, 214, and 216 as shown in more detail in the cross-section view of FIG. 2A.

During operation of the multipolar ESC 209 in FIGS. 2A-2B, the voltages applied to the electrodes 204, 206, 208, 210, 212, 214, and 216 are controlled to improve clamping, to reduce bow, and/or to achieve other results. For one example embodiment, one or more algorithms are used to apply voltages to the electrodes 204, 206, 208, 210, 212, 214, and 216 so that different electric fields are generated in an order and strength to facilitate the clamping provided by the multipolar ESC 209. For one example embodiment, the electric fields are generated and applied to reduce the bow in the microelectronic workpiece 112. For each of these example embodiments, electrostatic forces between the microelectronic workpiece and the multipolar ESC 209 can be shifted from the middle portion of the multipolar ESC 209 to the outer edge of the multipolar ESC 209 to facilitate the clamping and/or flattening of the microelectronic workpiece 112.

For further embodiments, one or more sensors can be used to detect bowing in the microelectronic workpiece 112, currents supplied to the electrodes within the multipolar ESC 209, and/or other conditions with respect to the multipolar ESC 209 and/or the microelectronic workpiece 112. The voltage supply algorithms can then be applied and/or adjusted based upon the parameters detected by these sensors. Other variations could also be implemented.

FIG. 2C is a process flow diagram of an example embodiment 270 where multiple electric fields generated between electrodes in a multipolar ESC are used to facilitate processing of a microelectronic workpiece. In block 272, a microelectronic workpiece is positioned on a multipolar electrostatic chuck (ESC). As described above, the multipolar ESC can include a dielectric body and multiple sets of electrodes formed within the dielectric body. In block 274, voltages are applied to the multiple sets of electrodes within the multipolar ESC to generate multiple electric fields between the multiple sets of electrodes. In block 276, the multiple electric fields are used to facilitate processing of the microelectronic workpiece. As described herein, for example, the multiple electric fields can migrate charge to edges of the microelectronic workpiece, can facilitate clamping of the microelectronic workpiece, can reduce bow in the microelectronic workpiece, and/or achieve other advantages. It is also noted that additional or different process steps could also be used while still taking advantage of the techniques described herein.

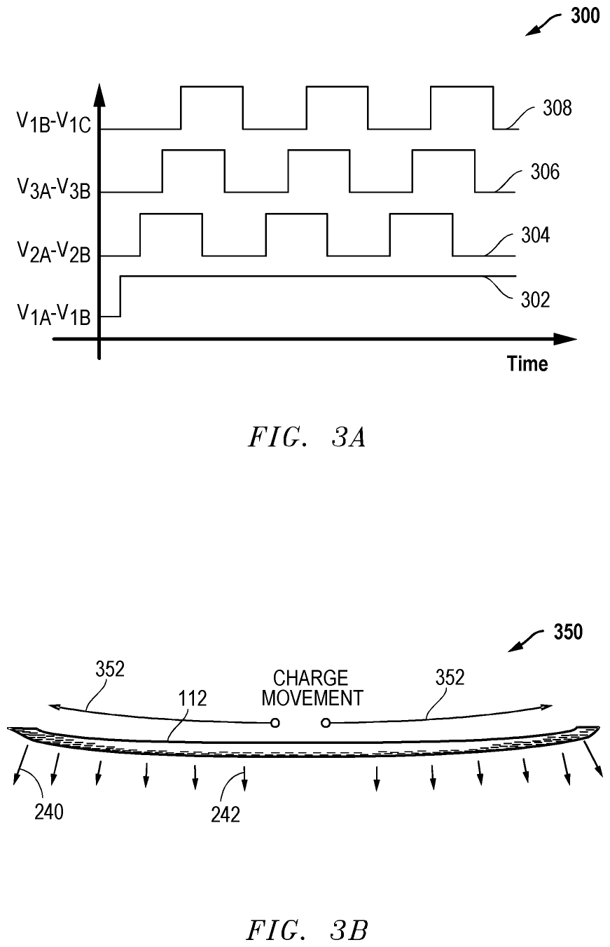

FIG. 3A is a timing diagram of an example embodiment 300 where one or more algorithms are applied to generate electric fields sequentially with respect to the electrodes 204, 206, 208, 210, 212, 214, and 216 in FIGS. 2A-2B. This sequential timing effectively migrates charge formed on the bottom surface of the microelectronic workpiece 112 to the edges of the microelectronic workpiece 112. This migration may be useful, for example, where bowing has occurred or has been detected to have occurred in the microelectronic workpiece 112.

For the example embodiment shown, a first electric field 302 is generated and maintained between electrodes 204 and 210 by applying a voltage differential between electrodes 204 and 210 using voltage (V_{1A}) 224 and voltage (V_{1B}) 230. This first electric field 302 causes charge to accumulate on the bottom, middle surface of the microelectronic workpiece 112. Next, a second electric field 304 is pulsed on and off between electrodes 206 and 212 by applying a varying voltage differential between electrodes 206 and 212 using voltage (V_{2A}) 226 and voltage (V_{2B}) 232. Next, a third electric field 306 is pulsed on and off between electrodes 208 and 214 by applying a varying voltage differential between electrodes 208 and 214 using voltage (V_{3A}) 228 and voltage (V_{3B}) 234. Next, a fourth electric field 308 is pulsed on and off between electrodes 210 and 216 by applying a varying voltage differential between electrodes 210 and 216 using voltage (V_{1B}) 220 and voltage (V_{1C}) 236. Further, for the example embodiment shown, the pulsed electric fields 304, 306, and 308 overlap each other. For example, the third electric field 306 starts while the second electric field 304 is on and turns off after the second electric field 304 has already been turned off. Similarly, the fourth electric field 308 starts while the third electric field 306 is on and turns off after the third electric field 306 has already been turned off. This sequential pulsing of electric fields 304, 306, and 308 progressively towards the edge of the microelectronic workpiece 112 causes charge accumulated on the bottom surface of the microelectronic workpiece 112 to migrate toward the edges of the microelectronic workpiece 112.

FIG. 3B is a diagram of an embodiment 350 where charge accumulated on the microelectronic workpiece 112 has migrated to the edge of the microelectronic workpiece based upon the sequential pulsing of electric fields 304, 306, and 308 as shown in FIG. 3A. As indicated by arrows 352, this sequential pulsing of electric fields 304, 306, and 308 progressively towards the edges of the microelectronic workpiece 112 causes accumulated charge to migrate toward the edges of the microelectronic workpiece 112. As such, the electrostatic force 240 generated at the edge of the microelectronic workpiece 112 is stronger as compared, for example, to the electrostatic force 242 generated closer to the center of the microelectronic workpiece 112. This increased force at the edges facilitates the clamping of the microelectronic workpiece 112 to the multipolar ESC 209, particularly where the microelectronic workpiece 112 is bowed. Further, this increased force at the edges helps to reduce the bow in the microelectronic workpiece 112. Other advantages can also be achieved.

It is noted that the multipolar ESC embodiments described herein may be utilized within a wide range of processing equipment including plasma processing systems. For example, the techniques may be utilized with plasma etch processing systems, plasma deposition processing systems, other plasma processing systems, and/or other types of processing systems.

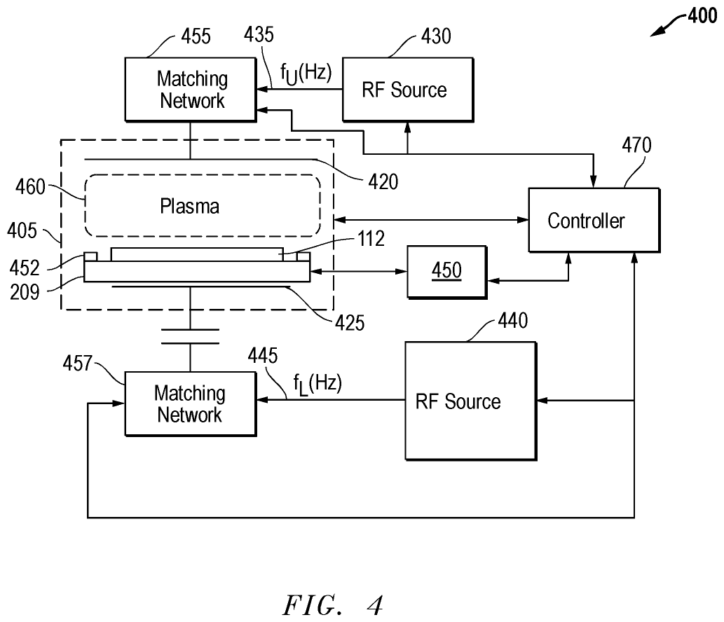

FIG. 4 provides one example embodiment for a plasma processing system 400 that can use the disclosed multipolar ESC embodiments and is provided only for illustrative purposes. The plasma processing system 400 may be a capacitively coupled plasma processing apparatus, inductively coupled plasma processing apparatus, microwave plasma processing apparatus, Radial Line Slot Antenna (RLSA™) microwave plasma processing apparatus, electron cyclotron resonance (ECR) plasma processing apparatus, or other type of processing system or combination of systems. Thus, it will be recognized by those skilled in the art that the techniques described herein may be utilized with any of a wide variety of plasma processing systems. The plasma processing system 400 can be used for a wide variety of operations including, but not limited to, etching, deposition, cleaning, plasma polymerization, plasma-enhanced chemical vapor deposition (PECVD), atomic layer deposition (ALD), atomic layer etch (ALE), and so forth. It will be recognized that different and/or additional plasma processing systems may be implemented while still taking advantage of the techniques described herein.

Looking in more detail to FIG. 4, the plasma processing system 400 may include a process chamber 405, and the process chamber 405 may be a pressure-controlled chamber. An upper electrode 420 and a lower electrode 425 may be provided as shown. The upper electrode 420 may be electrically coupled to an upper radio frequency (RF) source 430 through an upper matching network 455. The upper RF source 430 may provide an upper frequency voltage 435 at an upper frequency (f_{U}). The lower electrode 425 may be electrically coupled to a lower RF source 440 through a lower matching network 457. The lower RF source 440 may provide a lower frequency voltage 445 at a lower frequency (f_{L}).

As described above, a microelectronic workpiece 112 (in one example a semiconductor wafer) may be clamped in place by a multipolar ESC 209. As further described herein, voltages are applied to different sets of electrodes within the multipolar ESC 209 to generate different electric fields that clamp the microelectronic workpiece 112. For example, a voltage generator 450 can be configured using one or more algorithms to apply varying voltages to the electrodes within the multipolar ESC 209. The voltage generator 450 can include control circuits that implement the one or more algorithms, and a storage medium can also be used to store the one or more algorithms. Still further, one or more sensors 452 can also be associated with the microelectronic workpiece 112 and/or the multipolar ESC 209. The sensors 452 detect one or more parameters associated with the microelectronic workpiece 112 and/or the multipolar ESC 209, and the sensors 452 output these parameters to the voltage generator 450 and/or the controller 470. Other variations can also be implemented.

It is noted that the controller 470 can be coupled to various components of the plasma processing system 400 to receive inputs from and provide outputs to the components. As such, components of the plasma processing system 400 including the voltage generator 450, the multipolar ESC 209, and the sensors 452 can be connected to and controlled by the controller 470. The controller 470 can in turn can be connected to a corresponding memory storage unit and user interface (not shown). Various processing operations can be executed via the user interface, and various plasma processing recipes and operations can be stored in a storage unit. Accordingly, a given microelectronic workpiece can be processed within the plasma-processing chamber with various microfabrication techniques.

The controller 470 and/or the control circuits within the voltage generator 450 can be implemented in a wide variety of manners. For example, the controller 470 and voltage generator 450 can include one or more programmable integrated circuits that are programmed to provide the functionality described herein. For example, one or more processors (e.g., microprocessor, microcontroller, central processing unit, etc.), programmable logic devices (e.g., complex programmable logic device (CPLD)), field programmable gate array (FPGA), etc.), and/or other programmable integrated circuits can be programmed with software or other programming instructions to implement the functionality of a proscribed plasma process recipe. It is further noted that the software or other programming instructions can be stored in one or more non-transitory computer-readable mediums (e.g., memory storage devices, FLASH memory, DRAM memory, reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

In operation, the plasma processing apparatus uses the upper and lower electrodes to generate a plasma 460 in the process chamber 405 when applying power to the system from the upper RF source 430 and the lower RF source 440. Further, ions generated in the plasma 460 may be attracted to a substrate for the microelectronic workpiece 112. The generated plasma can be used for processing a target substrate (or any material to be processed) in various types of treatments such as, but not limited to, plasma etching, chemical vapor deposition, treatment of semiconductor material, glass material and large panels such as thin-film solar cells, other photovoltaic cells, organic/inorganic plates for flat panel displays, and/or other applications, devices, or systems.

Application of power results in a high-frequency electric field being generated between the upper electrode 420 and the lower electrode 425. Processing gas delivered to process chamber 405 can then be dissociated and converted into a plasma. As shown in FIG. 4, the exemplary system described utilizes both upper and lower RF sources. Other variations can also be implemented. In one example system, the sources may be switched (higher frequencies at the lower electrode and lower frequencies at the upper electrode). Further, a dual source system is shown merely as an example system and it will be recognized that the techniques described herein may be utilized with other systems in which a frequency power source is only provided to one electrode, direct current (DC) bias sources are utilized, or other system components are utilized.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

“Microelectronic workpiece” as used herein generically refers to the object being processed in accordance with the invention. The microelectronic workpiece may include any material portion or structure of a device, particularly a semiconductor or other electronics device, and may, for example, be a base substrate structure, such as a semiconductor substrate or a layer on or overlying a base substrate structure such as a thin film. Thus, workpiece is not intended to be limited to any particular base structure, underlying layer or overlying layer, patterned or unpatterned, but rather, is contemplated to include any such layer or base structure, and any combination of layers and/or base structures. The description below may reference particular types of substrates, but this is for illustrative purposes only and not limitation.

The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate; a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

Systems and methods for processing a microelectronic workpiece are described in various embodiments. One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the described systems and methods will be apparent to those skilled in the art in view of this description. It will be recognized, therefore, that the described systems and methods are not limited by these example arrangements. It is to be understood that the forms of the systems and methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A system, comprising:
a multipolar electrostatic chuck (ESC), comprising:
a dielectric body; and
multiple sets of electrodes formed within the dielectric body; and
a voltage generator coupled to the multiple sets of electrodes for the multipolar ESC, the voltage generator being configured to apply voltages to the multiple sets of electrodes to generate multiple electric fields between the multiple sets of electrodes.

2. The system of claim 1, wherein the multiple electric fields are configured to migrate charge to edges of a microelectronic workpiece.

3. The system of claim 1, wherein the multiple electric fields are configured to facilitate clamping of a microelectronic workpiece.

4. The system of claim 1, wherein the multiple electric fields are configured to reduce bow in a microelectronic workpiece.

5. The system of claim 1, wherein the multiple sets of electrodes comprises at least three sets of electrodes.

6. The system of claim 1, wherein the multiple electric fields are sequentially pulsed from a center of the dielectric body to outer edges of the dielectric body.

7. The system of claim 6, wherein pulsing for the multiple electric fields overlap with each other.

8. The system of claim 1, wherein one or more varying voltages are applied to the multiple sets of electrodes.

9. The system of claim 1, further comprising one or more sensors associated with a microelectronic workpiece.

10. The system of claim 9, wherein the voltage generator is further configured to adjust voltages applied to the multiple sets of electrodes based upon one or more parameters detected by the one or more sensors.

11. The system of claim 10, wherein the one or more parameters comprises a bow in the microelectronic workpiece.

12. A method, comprising:
positioning a microelectronic workpiece on a multipolar electrostatic chuck (ESC), the multipolar ESC comprising:
a dielectric body; and
multiple sets of electrodes formed within the dielectric body; and
generating multiple electric fields between the multiple sets of electrodes by applying voltages to the multiple sets of electrodes.

13. The method of claim 12, further comprising using the multiple electric fields to migrate charge to edges of the microelectronic workpiece.

14. The method of claim 12, further comprising using the multiple electric fields to facilitate clamping of the microelectronic workpiece.

15. The method of claim 12, further comprising using the multiple electric fields to reduce bow in the microelectronic workpiece.

16. The method of claim 12, wherein the generating comprises sequentially pulsing the multiple electric fields from a center of the dielectric body to outer edges of the dielectric body.

17. The method of claim 16, wherein the generating comprising overlapping the pulsing for the multiple electric fields.

18. The method of claim 12, wherein the generating comprises applying one or more varying voltages to the multiple sets of electrodes.

19. The method of claim 12, further comprising adjusting voltages applied to the multiple sets of electrodes based upon one or more parameters detected by the one or more sensors associated with the microelectronic workpiece.

20. The method of claim 19, wherein the one or more parameters comprises a bow in the microelectronic workpiece.
